(19) United States
(12) Patent Application Publication
(10) Pub. No.: US 2007/0187705 A1
(43) Pub. Date: Aug. 16, 2007

(54) ILLUMINATING DEVICE AND LIQUID CRYSTAL DISPLAY DEVICE USING THE SAME

(76) Inventors: Toshiaki Tanaka, Kodaira (JP); Hiroki Kaneko, Hitachinaka (JP); Ikuo Hiyama, Hitachinaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/624,229

(22) Filed: Jan. 18, 2007

(30) Foreign Application Priority Data
Feb. 15, 2006 (JP) 2006-037361

(51) Int. Cl. H01L 33/00

(52) U.S. Cl. 257/98

(57) ABSTRACT

An illuminating device is provided for enhancing evenness of a brightness distribution or a chromaticity distribution of a light-emitting diode device. The illuminating device is made up of a substrate, one or more light-emitting diode devices located on the substrate, a reflector plate located on the substrate, and a transparent resin for sealing the light-emitting diode. The transparent resin has a concave portion above the light-emitting diode device. Part of a ray emitted from the light-emitting diode device is reflected on the concave portion and then irradiated through the transparent resin. This allows the light-emitting diode device to have a maximum value of a luminous intensity in the perpendicular direction to a predetermined inclined direction against the substrate.

### BACKGROUND OF THE INVENTION

The present invention relates to a light source formed of light-emitting diode devices, and more particularly to a liquid crystal display device using the light source as its backlight.

A liquid crystal television set, which is a representative one of the liquid crystal display devices, has conventionally included a cold-cathode tube mounted therein as its backlight source. Recently, on the other hand, a module is being developed in which semiconductor light-emitting diode (abbreviated as LED) devices are applied to the backlight source. Unlike a small liquid crystal display device used for a cellular phone in which white LED devices have been mounted, as an important factor, a medium-sized or a large-sized liquid crystal television set needs to widen a color reproducible range and improve such high display performance as corresponding with a moving picture or a high-quality image by mounting LED devices of the primary colors of red, green and blue so that the LED devices may be controlled fast and independently. Hence, the medium-sized or the large-sized liquid crystal television set is required to use the LED devices that make this display performance possible for constructing a backlight module.

When constructing a light source of an illuminating device or a backlight module of a liquid crystal display device, it is important to achieve a large illuminating area in a quite narrow space. For making the display expansion and the illumination uniform and color mixture very efficient, the following arts have been known. As an prior art, for example, the below-described JP-A-10-173242, describes the lenses for the primary colors mounted on a resin molded body so that the corresponding luminous colors emitted from the red, the green and the blue LED devices are more likely to be mixed with one another. Since the luminous brightness appearing immediately above the LED device is so large, it is important to not keep the normal luminous distribution of the LED device but to make the luminous intensity larger and close to a maximum not in the center of the LED device but on the high angle side thereof.

On the other hand, the below-described JP-A-2003-8068 and JP-A-2003-8081 describe a resin lens covered on a package so that the color light rays are optically emitted horizontally or toward the high angle side. The mount of the resin lens makes it possible to control the irradiation angle distribution toward the high angle side. Further, the below-described JP-A-2004-319458 describes the backlight construction in which a quantity of light becomes maximum when an angle of irradiation is 45 degrees or more by providing a reflector plate (simply referred to as a reflector) with a convex portion with the LED device as its center, providing an LED device on an oblique surface, or controlling an angle of irradiation through a prism.

The foregoing JP-A publications describe the trials of controlling the distribution of an irradiation angle of an LED device. However, the trials do not provide a sufficiently high capability of overcoming disadvantageous distributions of bright spots and chromaticity, so that those trials do not realize even and stable brightness and chromaticity distributions. Further, since the brightness distribution is made even by providing the reflector, it is difficult to align the reflector with the LED device, so that these trials cannot sufficiently cope with lowering of luminous efficiency resulting from the control or coupling of the irradiation angle. Further, in a case that plural LED devices are arranged as a light source of a display element, it is necessary to consider the mutual influence of the brightness distributions of the LED devices with one another. Hence, the foregoing known techniques cannot sufficiently cope with the arrangement of plural LED devices.

The present invention is made to overcome these disadvantages, and it is an object of the present invention to provide an LED device which makes its brightness or chromaticity distribution more even and an illuminating device and a liquid crystal display device constructed to use the LED devices.

### SUMMARY OF THE INVENTION

In carrying out the foregoing object, according to an aspect of the present invention, an illuminating device includes a substrate, one or more LED device located on the substrate, a reflector located on the substrate, and a transparent resin for sealing the LED device, the transparent resin having a concave portion above the LED device so that part of a ray emitted from the LED device may be reflected on the concave portion and irradiated through the transparent resin, the LED device having a maximum luminous intensity in the perpendicular direction to the substrate to in a predetermined inclined direction, part of a ray having perpendicular components to the substrate, the ray being emitted from the LED device, being reflected on the concave portion and then irradiated through the transparent resin, and the concave portion being formed like a cone or a pile of conical sections or in a manner that an envelope is made smooth as gradually changing the curvature.

According to another aspect of the present invention, an illuminating device includes a substrate, one or more LED devices located on the substrate, and a transparent resin for sealing the LED device, the surface form of the transparent resin being a combination of a first form in which a ray emitted from the LED device is totally reflected, a second form being adjacent to the first form in which second form the irradiation angle of the totally reflected ray is adjusted, and a third form being adjacent to the second form in which third form an irradiation angle of the ray emitted from the LED device is adjusted in the direction perpendicular to the substrate, the first, the second and the third forms having respective distributions of irradiation angle, and the LED device having a maximum luminous intensity in the direction of the border between the second form and the third form.

According to another aspect of the present invention, a liquid crystal display device includes a light source having a housing, a plurality of LED devices located on the housing, and a transparent resin for sealing the LED devices, a liquid crystal display panel to which a ray of light is applied from the light source, and a diffusing plate located between the light source and the liquid crystal display panel, the LED devices being located on the housing periodically at predetermined intervals of d, the LED device having a maximum luminous intensity in the perpendicular direction to in the direction of an angle of θ to the housing when expressing the relation between the angle θ and a distance h between the housing and the plate of diffusion by θ=tan⁻¹(2 h/d), and the transparent resin having a concave portion on top of the LED device

The present invention provides an illuminating device which makes the brightness and the chromaticity distributions more even and a display device constructed to use the illuminating device as its backlight.

Other objects, features and advantages of the invention will become apparent from the following description of the embodiments of the invention taken in conjunction with the accompanying drawings.

### BRIEF DESCRIPTION OF THE DRAWINGS

FIG. 1 is a sectional view showing a construction of a packaged light source according to a prior art;

FIG. 2 is a sectional view showing a construction of a packaged light source according to a prior art;

FIG. 3A is a sectional view showing a process for producing the packaged light source according to a prior art;

FIG. 3B is a sectional view showing the process for producing the packaged light source according to a prior art;

FIG. 3C is a sectional view showing the process for producing the packaged light source according to a prior art;

FIG. 4A is a sectional view showing the process for producing a packaged light source according to the first embodiment of the present invention;

FIG. 4B is a sectional view showing the process for producing the packaged light source according to the embodiment of the present invention;

FIG. 4C is a sectional view showing the process for producing the packaged light source according to the first embodiment of the present invention;

FIG. 5 is a sectional view showing a construction of a packaged light source according to the first embodiment of the present invention;

FIG. 6 is a sectional view showing a construction of a packaged light source according to the first embodiment of the present invention;

FIG. 7 is a sectional view showing a construction of a packaged light source according to a second embodiment of the present invention;

FIG. 8 is a sectional view showing a construction of a packaged light source according to the second embodiment of the present invention;

FIG. 9 is a sectional view showing a construction of a packaged light source according to the second embodiment of the present invention;

FIG. 10 is a graph showing a complete diffused light distribution derived by calculation;

FIG. 11 is a graph showing a measured result of a distribution of a ray emitted from a sealed resin according to a prior art;

FIG. 12 is a graph showing a measured result of a distribution of a ray emitted from a sealed resin form provided in the second embodiment;

FIG. 13 is a graph showing a measured result of a flux of light derived in the presence or the absence of the resin form provided in the second embodiment;

FIG. 14 is a graph showing a measured result of luminous efficacy derived in the presence or the absence of the resin form provided in the second embodiment;

FIG. 15 is a graph showing a calculated result of a distribution of an emitted ray in the resin form area provided in a third embodiment of the present invention;

FIG. 16A is a sectional view showing a process for producing a packaged light source according to the third embodiment of the present invention;

FIG. 16B is a sectional view showing a process for producing a packaged light source according to the third embodiment of the present invention;

FIG. 16C is a sectional view showing a process for producing a packaged light source according to the third embodiment of the present invention;

FIG. 17 is a sectional view showing a construction of a packaged light source according to the third embodiment of the present invention;

FIG. 18 is a sectional view showing a construction of a packaged light source according to the third embodiment of the present invention;

FIG. 19 is a sectional view showing a construction of a packaged light source according to the third embodiment of the present invention;

FIG. 20 is a graph showing a measured result of a distribution of a ray emitted by the sealed resin form provided in the third embodiment;

FIG. 21 is a graph to be used for comparing a measured result with a calculated result of a distribution of a ray emitted by the sealed resin form provided in the third embodiment;

FIG. 22 is a top view showing a light source unit structure included in a backlight module according to a prior art;

FIG. 23 is a top view showing a construction of the backlight module include in a prior art;

FIG. 24A is a sectional view showing a construction of a packaged light source included in a prior art;

FIG. 24B is a graph showing an irradiation angle distribution of the packaged light source included in a prior art;

FIG. 25 is a top view showing a construction of a packaged light source included in the fourth embodiment;

FIG. 26 is a sectional view showing a construction of a packaged light source included in the fourth embodiment;

FIG. 27 is a top view showing a construction of a backlight module light source unit included in the fourth embodiment;

FIG. 28 is a top view showing a construction of a backlight module light source included in the fourth embodiment;

FIG. 29 is a top view showing a construction of a backlight module light source included in the fourth embodiment;

FIG. 30 is a top view showing a construction of a backlight module light source included in another embodiment of the present invention;

FIG. 31A is a sectional view showing a construction of a packaged light source included in the fourth embodiment;

FIG. 31B is a graph showing a distribution of an irradiation angle of a packaged light source included in the fourth embodiment;

FIG. 31C is a graph showing a distribution of an irradiation angle of a packaged light source included in the fourth embodiment;

FIG. 32 is a top view showing a construction of a packaged light source included in a fifth embodiment of the present invention;

FIG. 33 is a sectional view showing a construction of a packaged light source included in the fifth embodiment;

FIG. 34 is a top view showing a construction of a backlight module light source unit included in the fifth embodiment;

FIG. 35 is a sectional view showing a construction of a backlight module light source and a liquid crystal display device according to a sixth embodiment of the present invention;

FIG. 36 is a sectional view showing a construction of a backlight module light source and a liquid crystal display device according to the sixth embodiment of the present invention;

FIG. 37 shows a large-sized liquid crystal panel display device constructed to use the backlight module of the LED devices according to the sixth embodiment of the present invention; and

FIG. 38 shows a liquid crystal panel display device for a car navigation constructed to use the backlight module of the LED devices according to the sixth embodiment of the present invention.

### DESCRIPTION OF THE EMBODIMENTS

According to the present invention, a package is formed to have an LED device served as a light source of an illuminating device or a liquid crystal display device in light of an optical design. This optical design includes the schemes for overcoming the foregoing disadvantages. These schemes will be described below.

In the prior art, the LED device to be used as the ordinary illuminating device or the liquid crystal display device has a cannonball form or a surface mounting form. In these forms, a bright spot appears immediately above the LED device, so that the brightness or the chromaticity distribution is likely to occur with the LED device as the center. In the ranged packages, latticed brightness unevenness occurs or the difference of chromaticity in each area becomes remarkable so that color unevenness may occur.

In turn, the description will be oriented to means for achieving more even optical distribution through the effect of the overall form of a package according to the present invention. For positively suppressing brightness unevenness and color unevenness and keeping the backlight uniform, at first, it is important to keep the distribution of irradiation angles so that no bright spot may occur immediately above the LED device. Hence, it is necessary to design the distribution of irradiation angles by considering dimensions of an area to be illuminated. In order to meet these requirements, it is effective to suppress the brightness immediately above the LED device and keep the distribution of irradiation angles of the luminous components emitted from the LED device shifted to have a peak intensity at a larger irradiation angle than the perpendicular direction.

According to the present invention, for controlling the irradiation distribution of the LED device at a high angle, the reflector and the sealing resin are located as follows. The reflector is made up of a material having a sufficiently high reflection factor to the luminous components of the LED device. The suitable reflection factor of the material is at least 90% or higher. Further, as to the LED device located in the package, the reflector is thin enough no to impede the irradiation distribution of the LED device. Moreover, the reflector is formed to be so high as not to screen the luminous components emitted at an irradiation angle of 80 degrees or more by the reflector. The thickness and the height of the reflector makes it possible to keep the luminous components irradiated through the sealing resin at a high angle, those luminous components being emitted from the LED device. This design enables to reduce the luminous component loss resulting from passage of the luminous components into the inside of the reflector or scattering of the luminous components as much as possible. On the other hand, the ordinary packaged form brings about repetitive multiple reflections between the sealing resin and the reflector, which thus makes the light loss in the reflector remarkable. The present invention is capable of relatively suppressing the light loss in the reflector, thereby being able to improve the luminous efficacy.

Further, for realizing the irradiation distribution with its peak at a high angle, the resin for sealing the LD device is designed as follows. The sealing resin is designed to totally reflect most of the luminous components onto the area including the LED device as a minimum requirement so that the luminous components may be irradiated through the sealing resin at a high angle. The area where the luminous components are totally reflected covers the same area as the LED device or a bit larger area. This design causes most of the luminous components emitted immediately above the LED device to be guided at a large irradiation angle and the distribution of irradiation angles to have its peak at a high angle. Further, for controlling the distribution of irradiation angles, the sealing resin is formed as follows. As a second area, the sealing resin is designed to have an area formed to adjust the angle of irradiation against the totally reflected luminous components. Further, as a third area, the sealing resin is designed to cause the luminous components emitted from the LED device at a high angle to be irradiated from the sealing resin at the same angle or condensed through a lens with the same curvature as the sealing resin. The sealing resin designed to have these areas is integrally formed with the package. The resulting package makes it possible to reduce the light loss and control the irradiation angle distribution. The angle at which the light is irradiated is designed according to the dimensions of the illuminating device or the liquid crystal backlight module, so that the even brightness and chromaticity distributions may appear on the overall package.

The foregoing design according to the present invention makes it possible to suppress the light loss and improve the luminous efficacy of the LED device and thereby reduce the power consumption in the overall package. Further, the locational design of the LED device and the package also makes it possible to realize the even brightness and chromaticity distributions.

Later, the description will be oriented to the concrete modes for carrying out the present invention.

### First Embodiment

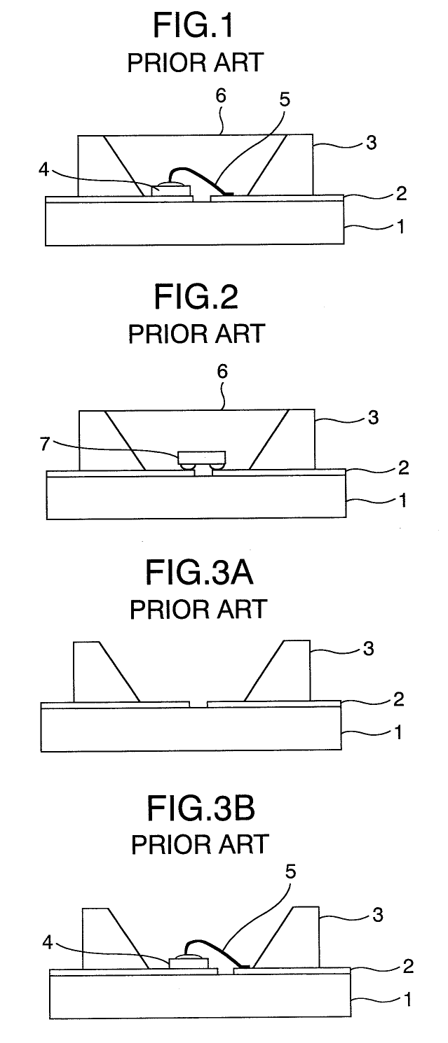

The first embodiment of the present invention will be described with reference to FIGS. 1 to 6.

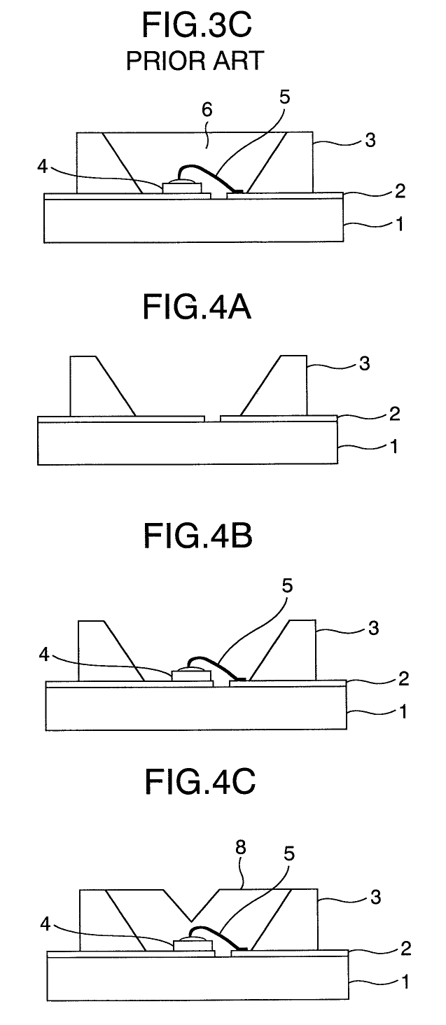

As shown in FIGS. 1 to 3A to 3C, conventionally, it is known that the LED device used as a light source of the illuminating device or the liquid crystal backlight module is built in a surface-mounting package. For example, as shown in FIGS. 1 and 2, an interconnecting line 2 is formed on a metal substrate provided with an insulated layer, a ceramic substrate, or a glass epoxy substrate. Then, a reflector 3 is integrally formed on the interconnecting line 2. Next, as shown in FIG. 1, a wire 5 is bonded for realizing the wire-bonding mounting of the LED device 4, while as shown in FIG. 2, a flip chip is bonded for realizing the flip-chip mounting of the LED device 4. Then, a transparent resin 6 is used for sealing the LED device. FIGS. 3A, 3B and 3C illustrate the foregoing process for producing the conventional LED device in the package. The reflector 3 may be bonded after the mounting of the LED device on the interconnecting substrate is finished. After the process shown in FIG. 3, the surface-mounting package is completed. The conventional surface-mounting package is formed to have such a bright spot as keeping the brightness higher around a spot located immediately above the LED device. Hence, this package disallows the irradiation distribution to be expanded far more and an even brightness distribution to be obtained in a light source provided in an integrated illuminating device or liquid crystal backlight module. On the other hand, it has been attempted that the use of a special lens component, known in the publications *2 and *3 causes the luminous components to be irradiated horizontally for expanding the irradiation distribution so that the even brightness distribution may be obtained in the integrated light source. However, the lens component is an independent element of the sealing resin of the LED device. Hence, the relevant alignment in the bonding process is required to be more precise. This brings about difficulty in the process for producing the surface mounting, thereby lowering the yield. Further, the complicated lens form, suggested in the publications, makes it difficult to adjust the horizontal irradiation angle and thereby to obtain the target irradiation angle distribution when designing the LED device in consideration of the illuminating area.

In the embodiment of the present invention, the LED device mounting and the surface mounting are implemented in a package form along the producing process as shown in FIGS. 4A, 4B and 4C. The LED device may be mounted by a wire-bonding technique or a flip-chip bonding technique. In both of the techniques, the surface-mounting package takes the same form. FIGS. 4A, 4B and 4C illustrate the wire-bonding mounting. In the process shown in FIGS. 4A and 4B, the package is produced in the same process as that of the prior art. The reflector 3 may be formed by the bonding process after the mounting of the LED device on the interconnecting substrate is finished. In FIG. 4C, a metallic die is used for producing the form of the transparent resin 8 so that the transparent resin 8 may be integrally bonded on the basal interconnecting substrate 1 and the reflector 3. Instead, the transparent resin 8 may be formed as shown by applying the cutting process. The transparent resin is formed as shown immediately above the LED device for sealing the LED device. In this forming process, a conical concave portion is formed in the transparent resin 8 in a manner to make the concave portion come closer to the LED device or the wire. It is preferable that the depth of the concave portion comes close to the LED device or the wire as much as possible so that the vertex of the cone may come closer to the same distance as or a lower distance than the thickness of the device. The form of the concave portion causes the most of the luminous components emitted vertically from the LED device to be totally reflected by adjusting the form and the angle of the oblique line indicating the section of the oblique surface of the concave portion. This concave form thus makes it possible to arrange the irradiation angle distribution so that an intensity peak appears at a larger irradiation angle than the vertical irradiation angle of 0 degree assuming that the vertical irradiation angle is 0 degree. This concave form realizes such a location as obtaining an even brightness distribution in a light source provided in an integrated illuminating device or liquid crystal backlight module.

In the embodiment of the present invention, in order to control the irradiation angle distribution so that the intensity peak appears at a larger angle than the vertical irradiation angle, the following components are required. That is, the important control factors are the form of the sealing resin, the relation of form between the LED device and the sealing resin, the relation of height between the sealing resin and the reflector, and so forth. At first, the form of the sealing resin is required to have a conical concave portion with a vertex opposed to the LED device and to control the width of the conical concave portion to be larger than the width of the LED device. Next, the vertex of the conical concave portion located as opposed to the LED device is provided closer to the LED device. In particular, the distance between the vertex of the conical concave portion and the LED device is characterized to come closer to the same thickness as or a smaller thickness than that of the LED device. Further, the vertex angle of the conical concave portion is characterized to be arranged in design so that the target irradiation angle distribution may be obtained. By meeting the foregoing requirements, it is possible to realize the target irradiation angle distribution of the present invention.

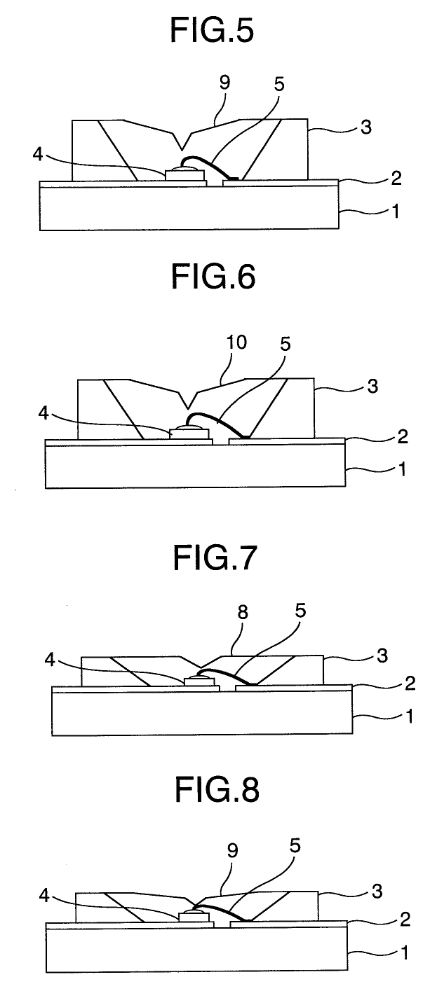

As the simplest structure of this embodiment, the sealing resin is formed so that one conical concave portion as shown in FIG. 4C is located immediately above the LED device. As shown in FIG. 5 or 6, on the other hand, another form of the sealing resin may be taken for realizing the target irradiation angle distribution. At first, as shown in FIG. 5, the sealing resin may be formed so that plural conical concave portions are piled. Further, as shown in FIG. 6, the sealing resin may be produced so that the sectional oblique line of the conical concave portion may be formed like an envelope curve. In both of the forms, the target irradiation angle distribution with no bright spot located vertically can be obtained.

In the package of this embodiment, since the reflective area of the surface of the sealing resin may be adjusted, it is possible to reduce the times of reflection between the resin surface and the reflector as much as possible as adjusting the irradiation angle of the luminous components emitted from the LED device. That is, the reduction of the reflection times leads to reduction of light absorption, thereby being able to suppress lowering of the luminous efficacy of the LED device though the light lost is small. It means that the overall package makes it possible to suppress the power consumption of the module. By controlling the sealing resin form of the LED device, it is possible to prevent occurrence of a bright spot immediately above the LED device and realize the irradiation angle distribution having an intensity peak at a target angle. This thus makes it possible to form the sealing resin properly according to the size of the illuminating device or the liquid crystal display device, thereby being able to make the brightness and the chromaticity even in the overall package. This also leads to the realization of even brightness and chromaticity though the number of the LED devices is reduced to a minimum. It means that the power consumption of the light source used for the illuminating device or the liquid crystal backlight module may be made lower. By applying the optimal minimum and location of the LED devices to the package, the present invention is effective in reducing the LED devices in number and thereby lowering the cost.

The packaged LED devices of this embodiment may be applied to the backlight module light source of the illuminating device or the liquid crystal display device of a small-sized to a large-sized TV set as well as to the light source to be installed in a car.

### Second Embodiment

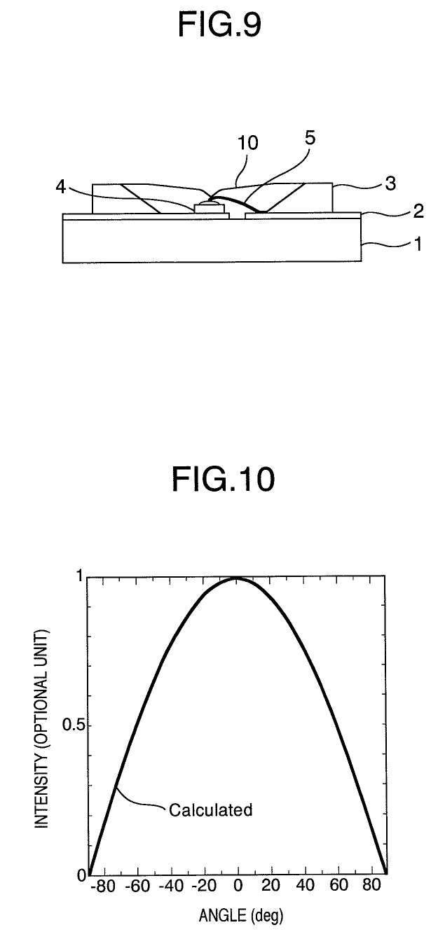

The second embodiment of the present invention will be described with reference to FIGS. 7 to 14.

In the second embodiment, like the first embodiment, the mounting of the LED device and the packaging thereof are implemented. Though the same package is formed in correspondence with FIGS. 4C, 5 and 6, in the second embodiment, the reflector 3 and the transparent resin 8, 9 or 10 for sealing the device are formed to be relatively thin. As shown in FIG. 7, 8 or 9, a conical concave portion is formed immediately above the LED device in the transparent resin 8 so that the concave portion comes closer to the LED device and the wire. The other components are completed by the same producing process as that of the first embodiment.

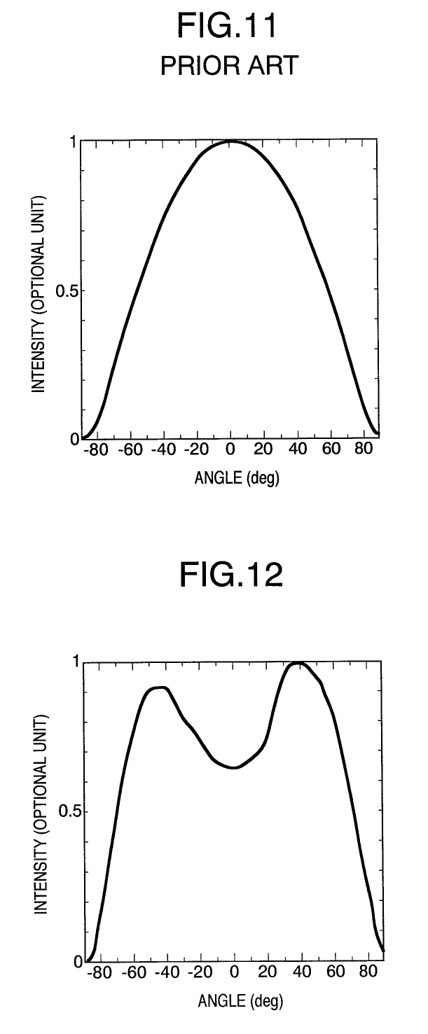

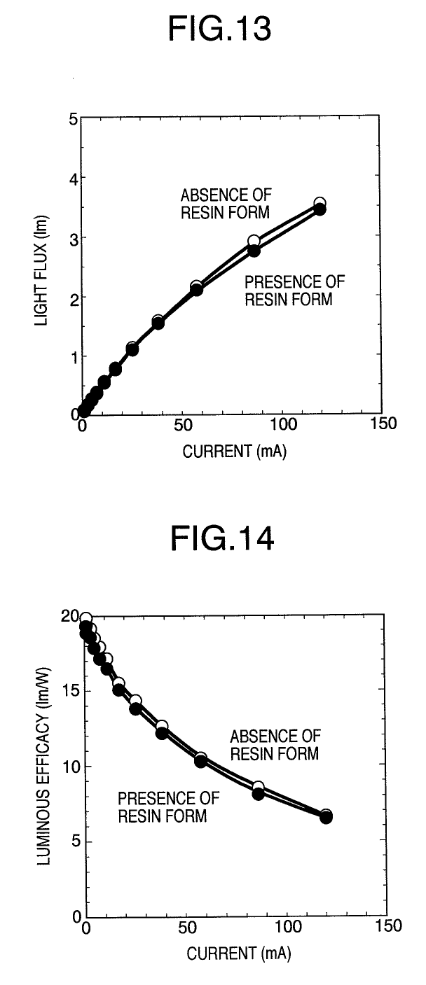

In the second embodiment, since the reflector is low, the light absorption and the scattering loss in the reflector are made smaller though the irradiation angle of the LED device is large, so that the luminous components irradiated through the sealing resin are increased. For example, even at an irradiation angle of 80 degrees or more, the luminous components may be irradiated without causing the sealing resin to screen those components, and the light quantity is increased and the light-irradiating efficiency is apparently improved. This is effective in adjusting the irradiation angle distribution and relatively effective in reducing the power consumption. Hereafter, a product to which the second embodiment is applied is shown with the relevant measured values. For relatively obtaining a more precise measured result of the irradiation angle distribution against the form of the sealing resin with respect to the LED device mounted on the substrate, at first, the irradiation angle distribution is measured after the package is temporarily sealed with the resin. Then, after the conical concave portion suggested about this embodiment is formed in the sealing resin, the irradiation angle distribution is measured. The measured results are compared and estimated. Concretely, at first, the irradiation angle distribution of the resin-sealed LED device was measured. As the references, FIG. 10 shows the calculated result that represents the Lambertian distribution, which outputs a diffused ray in an isotropic manner. FIG. 11 shows the irradiation angle distribution in the previous resin sealed state before producing the form of this embodiment. As shown in FIG. 11, the intensity distribution is not extremely lowered even at an irradiation angle of 80 degrees or some and the sealing resin does not screen the luminous components. Further, it is checked that the irradiation angle distribution shown in FIG. 11 traces the Lambertian distribution of the diffused ray shown in FIG. 10. Afterwards, by forming the conical concave portion of this embodiment as shown in FIG. 7, 8 or 9, it is possible to obtain the irradiation angle distribution shown in FIG. 12. It is understood from FIG. 12 that the package form produced according to this embodiment brings about an irradiation angle distribution in which the intensity of emitted components is lowered immediately above the LED device and an intensity peak appears at an irradiation angle of 40 degrees or more assuming that the vertical angle is 0 degree. It was found from this result that the irradiation angle distribution where a peak distribution appears in the direction of a high angle to in the perpendicular direction may be controlled. FIGS. 13 and 14 show the result of relatively checking the influence of the resin-formed LED device that controls this irradiation angle distribution on the optical characteristic. As a result of totally checking the light flux with an integrating sphere, as shown in FIGS. 13 and 14, it was found that the total light flux and the luminous efficacy changing depending on injected current are almost equal to those of the LED device with no resin form. It was thus found that the attenuation of a light quantity caused by the optical scattering loss is not so remarkable even in the case of producing the resin form. That is, it is found that the resin form produced according to this embodiment has a capability of keeping the optical characteristics such as the light flux and the luminous efficacy as controlling the irradiation angle distribution by arranging the optical design. It means that the light intensity distribution may be expanded without changing the optical characteristic and the light intensity distributions of the packages may be complemented with each other by using two or more resin-sealed LED device packages. Hence, the application of plural packaged LED devices to the light source module makes it possible to obtain even brightness on a wider plane.

The foregoing package is quite effective in the backlight module used for the illuminating device or the liquid crystal display device which module is required to control the irradiation angle distribution to a target specification. From a view of a way of use, the package form of the second embodiment may be applied to the similar technical field to the first embodiment.

### Third Embodiment

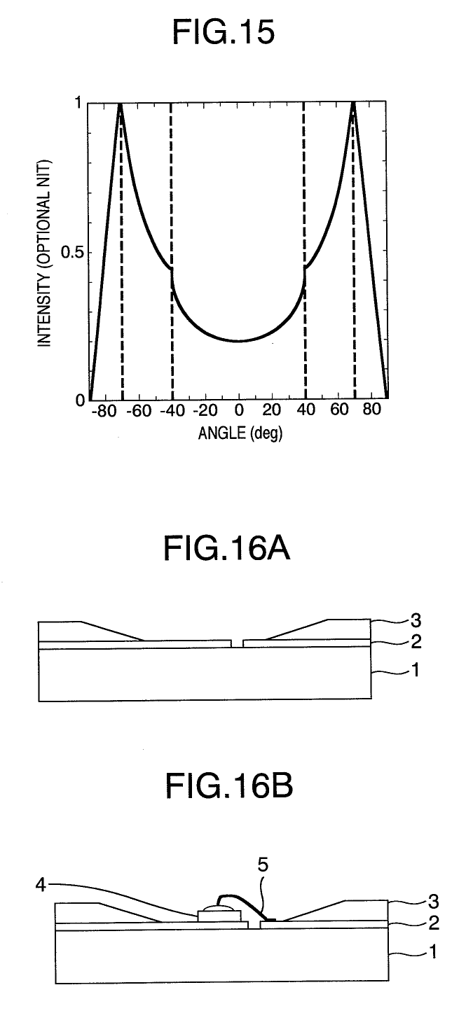

The third embodiment of the present invention will be described with reference to FIGS. 15 to 21.

In the third embodiment, the target irradiation angle distribution of the resin-sealed LED device package will be described below and the resin-sealed LED device package is formed to control the irradiation angle distribution along the below-described target distribution. In the resin used for integrally sealing the LED device, the resin to which the luminous components are emitted from the LED device is made up of at least three continuous areas with respective forms for controlling the irradiation angle distribution.

As to the first area, the sealing resin being as wide as or wider than the LED device is formed to totally reflect the luminous components emitted at a small irradiation angle covering the verticality. The second resin area located adjacent to the first area is formed to adjust the irradiation angle when the luminous components totally reflected on the first area are irradiated through the surface of the sealing resin. The third area is formed to refract the luminous components emitted from the LED device at a high angle or in the horizontal direction toward a lower angle side, for condensing the light. These forms allow the irradiation pattern of the luminous components irradiated from the sealing resin to be formed as an irradiation angle distribution that indicates an intensity peak at a larger irradiation angle than the vertical irradiation angle of 0 degree. As the important factors, at first, these first to third areas are continuously connected so that the corresponding irradiation angle distributions may be continuously connected as one distribution. Secondly, the irradiation angle distribution is formed so that a peak value of the light irradiation intensity appears on the border between the second and the third areas.

The foregoing optical design specification will be described with reference to FIG. 15. In this embodiment, the form of the resin for sealing the LED device is divided into the foregoing three areas. In actual, as shown in FIG. 15, the area for a low irradiation angle is assumed as an area I, the area for a middle irradiation angle, adjacent to the area I, is assumed as an area II, and the area for a high irradiation angle, adjacent to the area II, is assumed as an area III. The irradiation angle distribution is specified on the following specifications of these three areas. The area I is an area that is as wide as or wider than the area of the LED device in real space. This area has a conical concave portion. In this form, most of the luminous components emitted upward from the LED device are totally reflected inside the sealing resin and are guided to the area for a higher angle. The irradiation angle distribution in the area I will be described as follows. Letting θ be an irradiation angle, n₁ be a refractive index of the sealing resin, and n₂ be a refractive index of a medium located on the side where the luminous components are emitted, the irradiation angle distribution includes an intensity distribution represented by f(θ)=a/cos(sin⁻¹(n₁ sin(θ)/n₂) ) (a is a constant). This makes it possible to suppress the bright spots strongly viewed from the packaged light source in the conventional area for a low irradiation angle and widen the intensity distribution toward a higher irradiation angle. The irradiation angle distribution in the area II will be described as follows. The area II for a middle angle is formed to adjust the irradiation angle of the irradiation components totally reflected on the area I. Letting θ be an irradiation angle, b be a constant, and m be an index, the irradiation angle distribution is formed like the intensity distribution represented by f(θ)=b/cos^{m}(θ). This allows the area II to be connected with the area III adjacent thereto and an intensity peak of the irradiation angle distribution to appear on the border between the area II and the area III. It is characterized that when designing the area II, the area II may be specified to the area with an intensity peak according to the arrangement of the packaged devices and the total design of the backlight module. The area III for a high angle is continuously connected with the form specified in the area II and has a function of refracting the luminous components emitted at a high angle toward a lower angle side. It is preferable to form this area III as a lens form that dynamically refracts the luminous components to be emitted at a high angle or horizontally toward a lower angle side for condensing light. The irradiation angle distribution that meets this form is formed like the intensity distribution represented by f(θ)=c cos n(θ) (c and n are constants) or is spherically formed like the intensity distribution represented by f(θ)=c(1-(1-(θ/90)²) (c is a constant). By adjusting the form of the sealing resin of the LED device, it is characterized that the areas I, II and III may be formed, the irradiation pattern of the luminous components of the LED device becomes a larger irradiation angle than the irradiation angle of 0 degree, that is, the vertical angle, and the irradiation angle distribution is formed to have a light irradiation intensity peak on the border between the area II and the area III.

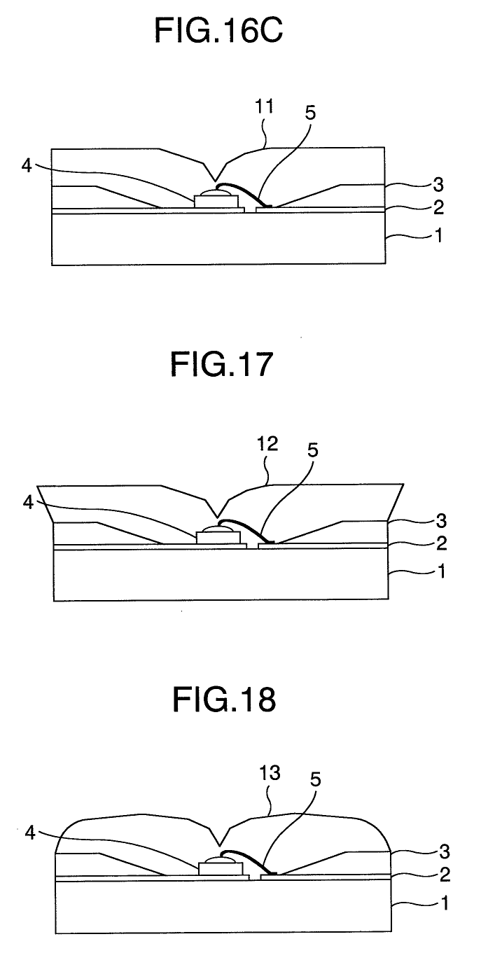

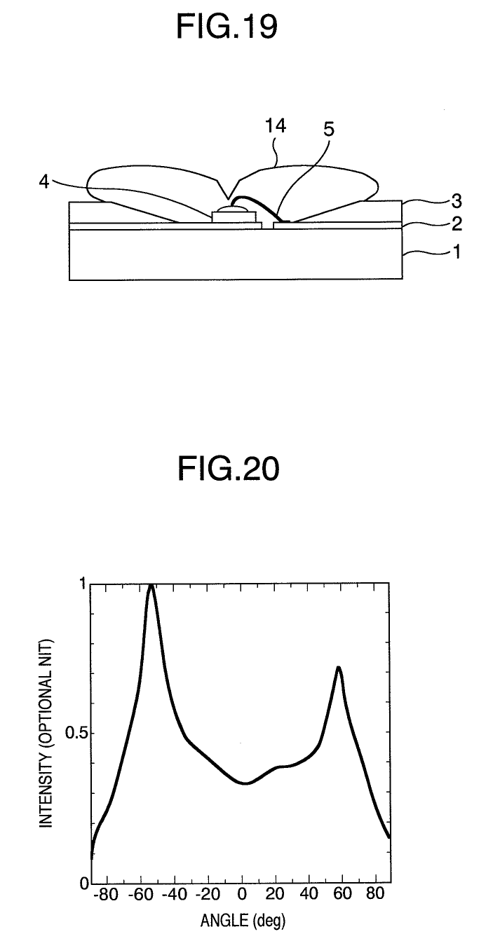

The form of the sealing resin according to this embodiment will be described below. Like the first and the second embodiments, as in this embodiment, the package with the LED device mounted therein is produced. In this embodiment, however, the package is produced so that the resin for sealing the LED device is higher than that of the first or the second embodiment. Further, the form of the resin is produced in correspondence with the form of the area I, II or III. The package is formed by the producing process as shown in FIGS. 16A to 16C. A sealing resin 11 having a concave portion for totally reflecting the emitted light located immediately above the LED device is formed in a manner to cover the reflector 3 being thinner than that of the first or the second embodiment. The side of the sealing resin is formed to have a vertical surface. In the form shown in FIG. 17, the sides of the sealing resin 12 are formed like a reverse-tapered slope. In the form shown in FIG. 18, the sides of the sealing resin 13 are curved to have a smooth curvature and is connected with the reflector 3. In the form shown in FIG. 19, the sides of the sealing resin 14 are each formed to have an area curved with a curvature and for reflecting light toward a higher angle side and a lens-shaped area for condensing light to the area for a high irradiation angle and are connected with the reflector 3.

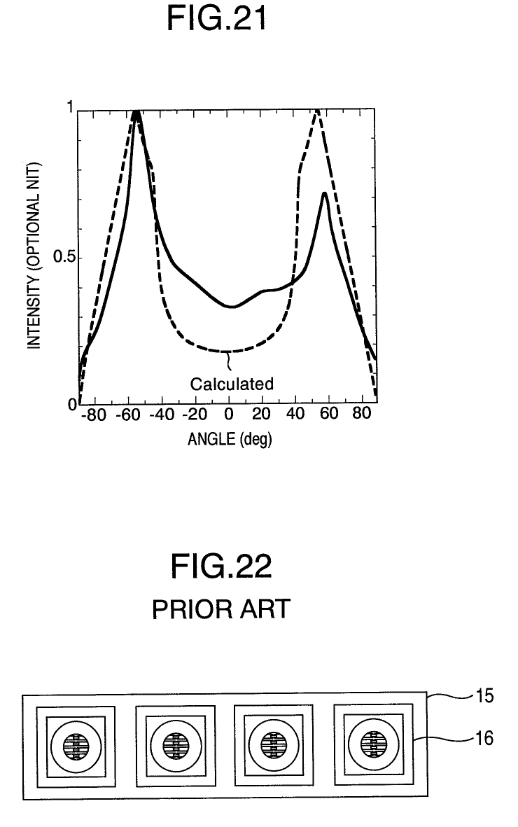

In this embodiment, the package is formed so that the reflector is lower, the sealing resin is higher and the area for a high irradiation angle is shaped like a lens. Hence, the irradiation angle distribution is characterized to more clearly indicate a peak value on the border between the areas II and III. When producing the form of the sealing resin according to this embodiment, as shown in FIG. 20, the package may be formed to have an irradiation angle distribution that indicates a peak value of the light irradiation intensity in the range of an irradiation angle of 55 to 60 degrees, which is larger than the irradiation angle of 0 degree. As a result, the irradiation angle distribution may be formed to have a lower light irradiation intensity in the central area for a low angle and a larger light irradiation intensity in the range where an irradiation angle area is narrowed toward a high angle side and to make the peak sharper than the package shown in FIG. 12 formed according to the second embodiment. FIG. 21 shows the measured result of FIG. 20 as comparing the calculated values of the irradiation angle distribution set in designing the package on the assumption that the three areas shown in FIG. 15 are formed. The measured result indicates closer values to angles of peak values derived in the calculated result of the irradiation angle distribution represented in a dotted line and is approximate to the calculated result thereof. It means that the produced resin form is set according to the target. It is indicated that the light intensity of the central area for a low angle is suppressed to a half of or less than the calculated result and is closer to the calculated value. It is found that by comparing the measured result with the calculated result, the actual irradiation angle distribution may be controlled along the designing specification of this embodiment in which the irradiation angle distribution is divided into three areas.

The irradiation angle distribution obtained by measuring the values of the resin-sealed package according to this embodiment is effective in dispersively expanding the light flux toward a high angle side or complementing the light flux in a specific irradiation angle area as suppressing the bright spots in the center. When forming plural packages in the backlight module of the illuminating device or the liquid crystal display device, it is important for those packages to complement the emitted light intensities with each other for making the brightness and the chromaticity even.

Further, in this embodiment, the high-angle area of the irradiation angle distribution is greatly improved. That is, even for a large angle in the irradiation angle distribution, the emitted light may be effectively taken out. By precisely designing and controlling the form of each sealing resin side, it is possible to increase a quantity of light emitted from the sealing resin side and make the precisely designed form contribute to the irradiation angle distribution. This makes it possible to apparently increase a quantity of light and improve the efficiency of irradiating light out of the sealing resin. This is effective in arranging the irradiation angle distribution and is more advantageous in reducing the power consumption as a result of improving the efficiency. This embodiment enables to expand the light intensity distribution. Further, since plural packages each having the resin-sealed LED device are used in this embodiment, the light intensity distributions of plural packages may be complemented with each other. These advantages indicate that the application of plural packages to the light source module makes brightness uniform on a wider plane. From a view of way of use, the third embodiment may be applied to the similar technical fields to those of the first or the second embodiment.

### Fourth Embodiment

The fourth embodiment of the present invention will be described with reference to FIGS. 22 to 31.

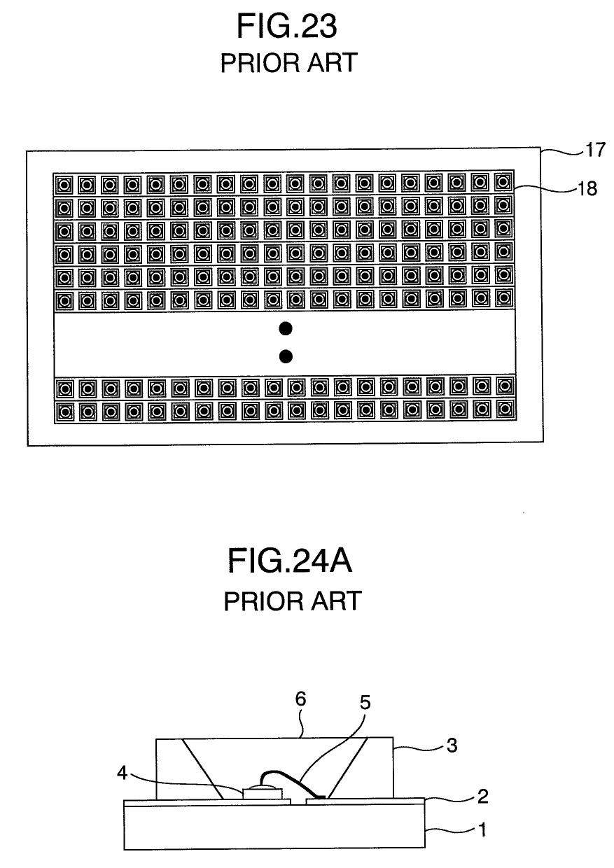

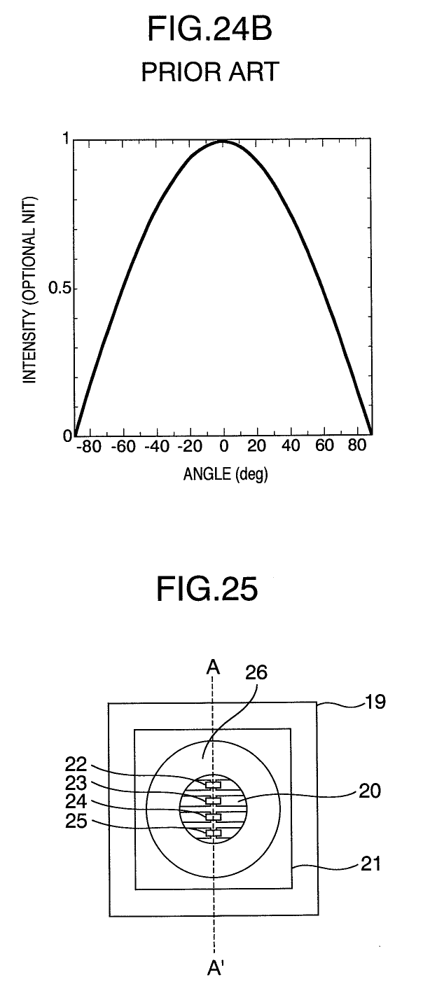

The description of the fourth embodiment concerns with the application of packages with an LED device to the backlight module of the liquid crystal display device. In the liquid crystal backlight module, conventionally, the area to be illuminated by a light source is limited to a narrow one, so that lots of packages are bedded in a housing matched in size with the liquid crystal panel. For example, an interconnecting substrate 18 as shown in FIG. 22 is composed of the LED packages ranged and mounted on a wiring substrate 15 and is mounted on a module housing 17 shown in FIG. 23. Since the package shown in FIG. 24A is not sealed by resin, which is a feature of the invention, the irradiation angle distribution is made to be the Lambertian distribution that indicates the normal diffused light. In actual, the irradiation angle distribution is formed as shown in FIG. 24B. That is, in the unit package, the bright spot of the highest brightness appears immediately above the LED device. The integration of the packages as shown in FIG. 23 by bedding them in the housing is suitable for making the brightness and the chromaticity even. However, since the devices and the packages are increased in number, the power consumption is increased accordingly and the total cost of the component members is made high. Further, in the producing process, the producing steps of mounting the LED device and connecting the packages are likely to be increased in number. This leads to disadvantageously extending the time taken in the producing process and lowering the process yield, which enhances the total cost of the backlight module.

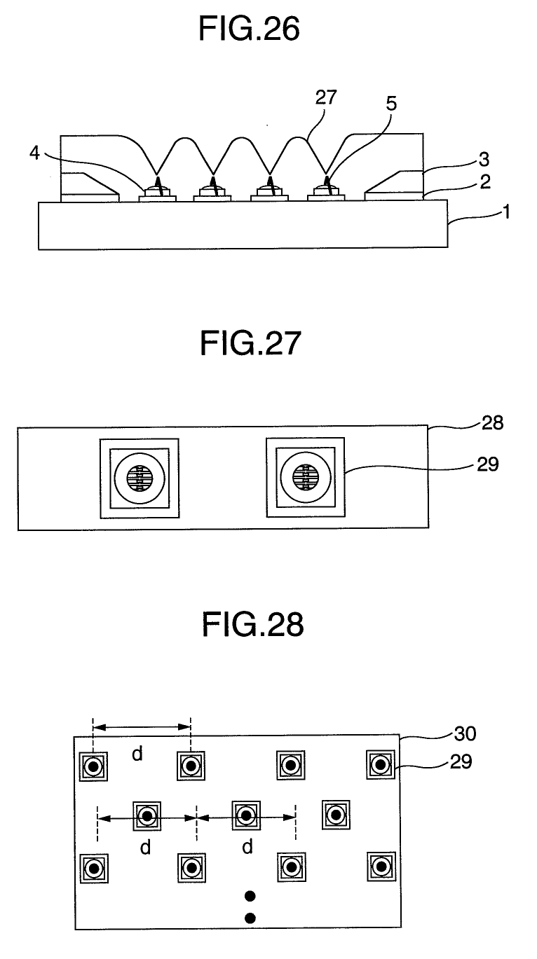

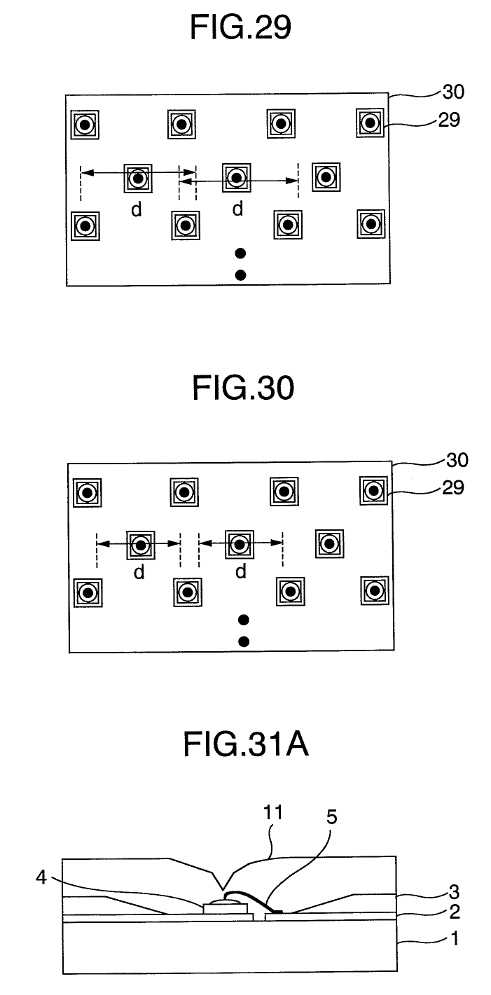

In this embodiment, in order to overcome these disadvantages of the prior art, for example, the packages, the top of which is shown in FIG. 25 and the section of which is shown in FIG. 26, are located and connected in the backlight module housing discretely, concretely, in a triangular-latticed manner or a staggered manner. In the package shown in FIG. 17, an interconnecting line 20 and a reflector 21 are formed on an interconnecting substrate 19 served as a ground, a red LED device 22, a green LED device 23, a green LED device 24 and a blue LED device 25 are mounted on the resulting interconnecting substrate 19, and then the substrate is sealed by a resin 26. This sealing resin 26 is formed like a sealing resin 27 having a total reflecting area located immediately above each of the red LED device 22, the green LED device 23, the green LED device 24 and the blue LED device 25 as shown in the section of FIG. 18 showing the sectional structure cut on the line A to A′ line of FIG. 25. This form makes it possible to provide each LED device with a target irradiation angle distribution. The packages shown in FIG. 25 may be mounted on the interconnecting substrate 28 as shown in FIG. 27 and then be placed in the backlight module housing. Or, the packages shown in FIG. 25 may be directly connected and placed in the backlight module housing. In FIG. 28 the packages 29 are located in the backlight module housing 30 in a discrete manner, that is, a triangular-latticed manner or a staggered manner. In this case, the packages 29 are located according to the size of the liquid crystal panel display device. Further, with the irradiation angle distribution about the package 29, letting d be a distance at which a peak value of the irradiation intensity, the distance may be matched to the distance d between the adjacent packages. By setting a peak of the irradiation intensity distribution to the area of this locational arrangement where the light intensity becomes the lowest, it is possible to keep the brightness distribution and the chromaticity distribution even. For setting target brightness and chromaticity distributions depending on some factors of the liquid crystal display device such as the size and the using conditions, it is possible to put emphasis on a mixture degree of the irradiation angle distribution to the luminous pattern by crossing the distance d that indicates a peak value of the irradiation intensity distribution viewed from the package as shown as the locational arrangement in FIG. 29. Further, it is possible to weaken the mixture degree of the irradiation angle distribution to the luminous pattern by keeping the distance d of one package spaced from the distance d of the adjacent package as the locational arrangement shown in FIG. 30. These locational arrangements may be effectively adjusted depending upon some factors of the liquid crystal display device such as the size and the using conditions.

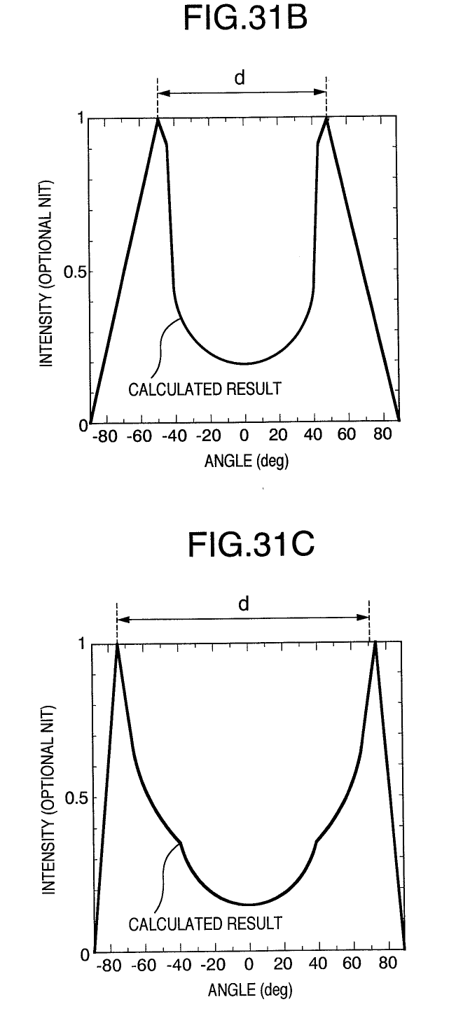

In this embodiment, by adjusting the sealing resin form of the package shown in FIG. 31A, it is possible to design the distance d that brings about an intensity peak of the irradiation angle distribution and set the irradiation angle that indicates an intensity peak to a target angle. This possibility will be described with reference to the calculated results shown in FIGS. 31B and 31C. It is understood that the design of the irradiation angle distribution and the adjustment of the sealing resin form allow the required specification of the backlight module light source to be set to target conditions depending upon the factors of the liquid crystal display device such as the size and the using conditions. This embodiment thus makes it possible to expand the light intensity distribution and complement the light intensity distributions of the packages with each other by locating plural packages each having the resin-sealed LED device. This embodiment is suitable to the light source module composed of plural packages so that even brightness may be obtained on a wider plane. With respect to the way of use, this embodiment may be applied to the similar technical field to that of the first, the second or the third embodiment.

### Fifth Embodiment

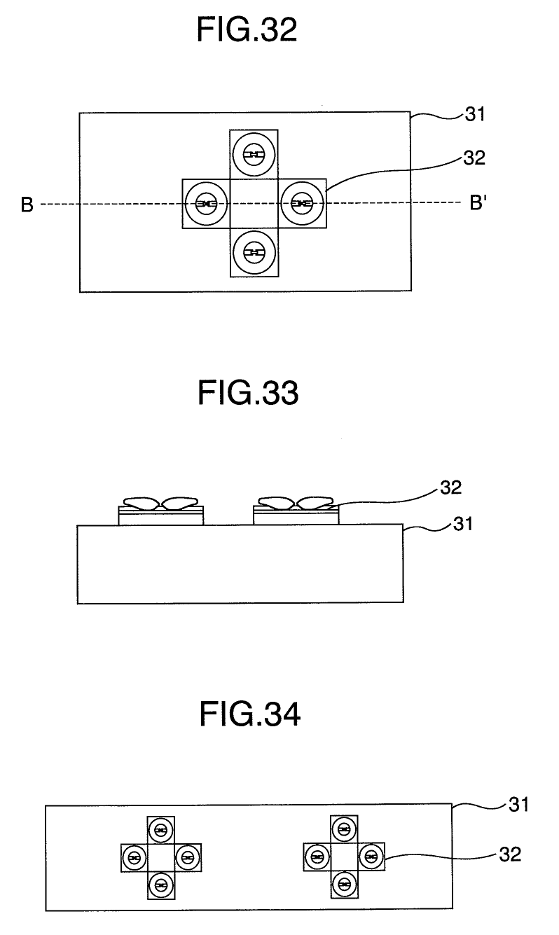

The fifth embodiment of the present invention will be described with reference to FIGS. 32 to 34.

Like the fourth embodiment, the description of this embodiment concerns with the application of this embodiment to the backlight module of the liquid crystal display device. Like the fourth embodiment, the package and the backlight module are produced in this embodiment. In the package, as shown in FIG. 32, a red LED device, a green LED device, the green LED device and the blue LED device are respectively are packaged on the interconnecting substrate 31. The corresponding four packages are connected as one package combination 32. The section of FIG. 33 corresponds to the section of FIG. 32 cut on the B-B′ line. In FIG. 34, one package combination is mounted and loaded on the interconnecting substrate 31 structured as a unit. The unit structure shown in FIG. 34 mounted and loaded in the backlight module housing as described with respect to the fourth embodiment may be used for the backlight source of the liquid crystal display device.

In this embodiment, since the irradiation angle distribution may be designed and the form of the sealing resin may be adjusted with respect to each package mounted with one LED device, the design and the irradiation angle distribution may be realized more precisely, which makes the evenness of the brightness distribution and the chromaticity distribution more controllable. Further, the specification of the required backlight module light source may be more easily set to the target conditions depending upon the factors of the liquid crystal display device such as the size and the using conditions.

For example, the arrangement of the packages each having one LED device mounted therein will be described as follows. In the backlight module composed of the ranged packages, the packages are located periodically at given intervals of d, and the arrangement of the packages may be designed so that the irradiation pattern of the luminous components emitted from the sealing resin indicates the intensity peak at an irradiation angle θ corresponding with θ=tan⁻¹(2 h/d) in which h denotes a distance between the package and a diffusing plate corresponding to one component of an optical system of the liquid crystal display device. Therefore, this fifth embodiment provides the liquid crystal display device that is characterized by the backlight module on which the packages each having the foregoing irradiation angle distribution are loaded.

With respect to the way of use, this embodiment may be applied to the similar technical field of that of the first, the second or the third embodiment.

The sixth embodiment of the present invention will be described with reference to FIGS. 35 to 38.

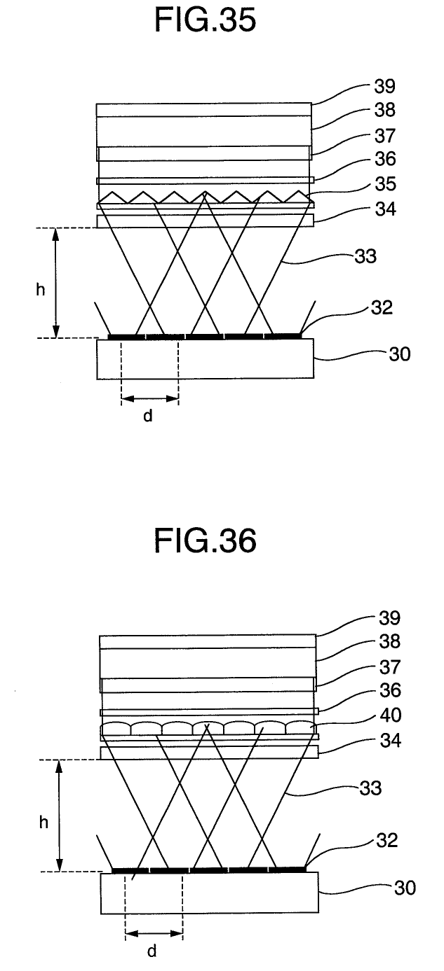

This sixth embodiment concerns with the application of the backlight module light source according to the foregoing fifth embodiment to the liquid crystal panel display device. As shown in FIG. 35, the liquid crystal display device is produced by mounting and loading a package 32 on the backlight module housing 30 and fitting an optical system like an optical sheet to the liquid crystal panel. The ray of light 33 emitted from the backlight module light source passes through a diffusing plate 34, a prism sheet 35, a diffusing film 36, a lower polarizing plate 37, a liquid crystal panel 38 having a thin-film transistor circuit and a color filter, and an upper polarizing plate 39. In this arrangement, it is possible to design the liquid crystal panel display device so that the irradiation angle distribution may have an intensity peak at an angle θ meeting the relation of tan θ=2 h/d in the case that h denotes a distance between the package light source and the diffusing plate. That is, by controlling the irradiation angle distribution in design according to the distance between the package light source and the diffusing plate, it is possible to make the brightness distribution and the chromaticity distribution of the backlight module light source more even. The arrangement shown in FIG. 36 is the same as the arrangement shown in FIG. 27 except that the prism sheet 35 is replaced with a lenticular lens sheet 40. Also in this case, it is possible to design the liquid crystal display device so that the irradiation angle distribution may be set to have an intensity peak at an angle θ meeting the relation of tan θ=2 h/d in the case that h denotes a distance between the package light source and the diffusing plate. Further, the lenticular lens sheet serves to improve the brightness of the liquid crystal panel viewed from the front. The diffusing and reflecting film may be integrally combined with the lower surface of the lenticular lens sheet. By pasting the diffusing and reflecting film with the lower surface of the lenticular lens sheet and locating the diffusing and reflecting film with a slit for a lens area, it is possible to cause the irradiation distribution components entered into the lens to improve the brightness of the liquid crystal panel viewed from the front and the irradiation distribution components not directly entered into the lens to be reflected on the diffusing and reflecting film for mixing the irradiation distributions and then cause the mixed irradiation distributions to be entered into the lens again, for the purpose of improving the brightness of the liquid crystal panel viewed from the front. This arrangement makes it possible to effectively use the backlight source, thereby making the backlight module more efficient and the evenness of the brightness distribution or the chromaticity distribution more controllable. Further, it is possible to more easily set the specification of the required backlight module light source to the target conditions depending upon the factors of the liquid crystal panel display device such as the size and the using conditions.

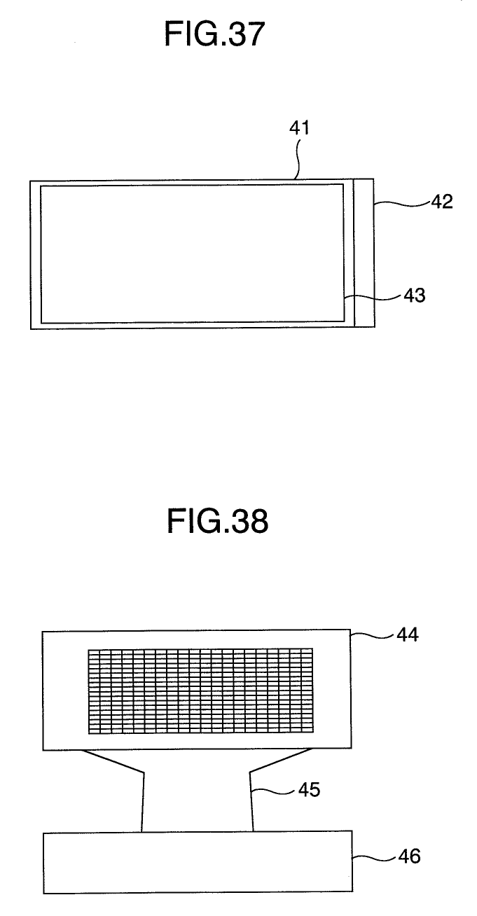

This sixth embodiment may be applied to the way of use of the foregoing fifth embodiment. In particular, it may be applied to the liquid crystal panel display device and the backlight module used for a middle-sized or a large-sized TV set. FIG. 37 shows the arrangement of a backlight module 41, a control circuit and a driving circuit 42 of the backlight module, and the liquid crystal panel. FIG. 38 shows the liquid crystal display device to be used for a car navigation, which is arranged to have a liquid crystal display device 44 having the backlight module and the optical system, a circuit wiring 45 and a driving circuit 46.

According to the present invention, the backlight module whose irradiation angle distribution is to be controlled is served to keep the brightness distribution and the chromaticity distribution even according to demand, irrespective of the size of the liquid crystal display device.

The present invention may be applied to a white light source of high luminous efficacy that keeps the output and the brightness high as well as the backlight module and the backlight source to be used for a large-sized liquid crystal display device for a large TV set and a small-sized or a middle-sized liquid crystal display device for a cellular phone or a personal computer.

It should be further understood by those skilled in the art that although the foregoing description has been made on embodiments of the invention, the invention is not limited thereto and various changes and modifications may be made without departing from the spirit of the invention and the scope of the appended claims.

1. An illuminating device comprising:
a substrate;
one or more light-emitting diode devices located on said substrate;
a reflector plate located on said substrate;
a transparent resin for sealing said light-emitting diode device;
said transparent resin having a concave portion above said light-emitting diode device;
part of a ray emitted from said light-emitting diode being reflected on said concave portion and then irradiated from said transparent resin; and
said light-emitting diode device having a maximum value of a luminous intensity in the perpendicular direction to a predetermined inclined direction against said substrate.

2. The illuminating device as claimed in claim 1, wherein the emitted ray having components perpendicular to said substrate, said ray being emitted from said light-emitting diode device, is reflected on said concave portion and then irradiated from said transparent resin.

3. The illuminating device as claimed in claim 1, wherein said concave portion is conical.

4. The illuminating device as claimed in claim 3, wherein said conical portion is formed of a pile of conical sections.

5. The illuminating device as claimed in claim 3, wherein said conical portion has a curvature being gradually changed so that an envelope curve is smooth.

6. An illuminating device comprising:
a substrate;
one or more light-emitting diode devices located on said substrate;
a transparent resin for sealing said light-emitting diode device; and
said transparent resin having a surface formed of a first form for totally reflecting a ray emitted from said light-emitting diode device, a second form being adjacent to said first form and for adjusting an irradiation angle of said totally reflected ray, and a third form being adjacent to said second form and for adjusting said irradiation angle of said ray emitted from said light-emitting diode device so that said ray is condensed perpendicularly to said substrate.

7. The illuminating device as claimed in claim 6, wherein said first, second and third forms have their respective irradiation angle distributions.

8. The illuminating device as claimed in claim 6, wherein said light-emitting diode device has a maximum value of a luminous intensity in the perpendicular direction to the predetermined inclined direction against said substrate.

9. The illuminating device as claimed in claim 8, wherein said light-emitting diode device has a maximum value of a luminous intensity toward the border between said second form and said third form.

10. A liquid crystal display device comprising:
a light source having a housing, plural light-emitting diode devices located in said housing, and a transparent resin for sealing each of said light-emitting diode devices;
a liquid crystal display panel to which a ray is irradiated from said light source;
a diffusing plate located between said light source and said liquid crystal display panel;
said light-emitting diode devices being located periodically at given intervals of d; and
said light-emitting diode devices having a maximum value of a luminous intensity in the perpendicular direction to the direction of an angle T against said housing in the case that letting h be a distance between said housing and said diffusing plate, said angle θ is expressed by θ=tan⁻¹(2 h/d).

11. The liquid crystal display device as claimed in claim 10, wherein said transparent resin has a concave portion above each of said light-emitting diode devices.
